(19) United States
(12) Patent Application Publication
(10) Pub. No.: US 2026/0360891 A1
(43) Pub. Date: Nov. 12, 2026

(54) COMPOSITE ARTICLE WITH ELECTROMAGNETIC INTERFERENCE SHIELDING AND METHOD OF FORMING

(71) Applicant: INTERNATIONAL AUTOMOTIVE COMPONENTS GROUP NA, INC., Southfield, MI (US)

(72) Inventors: Benedetto REGINELLA, Bradford, Ontario (CA); Mason KOUHI, Commerce Township, MI (US); David Mark PASCOE, Aurora, Ontario (CA)

(21) Appl. No.: 19/122,434

(22) PCT Filed: Oct. 25, 2023
(86) PCT No.: PCT/US2023/077744

§ 371 Date: Apr. 18, 2025

Related U.S. Application Data
(60) Provisional application No. 63/380,897, filed on Oct. 25, 2022.

(51) Int. Cl. H01M 50/24; B29C 45/14; B29K 105/00; B29K 105/20; B29L 31/00; H01M 50/249

(52) U.S. Cl. CPC H01M 50/24; B29C 45/1418; B29C 45/14639; H01M 50/249; B29K 2105/0026; B29K 2105/206; B29K 2995/0011; B29K 2995/0097; B29L 2031/7146; H01M 2220/20

(57) ABSTRACT

The present disclosure relates to a composite article and method of forming, that preferably provides electromagnetic interference (EMI) shielding of an enclosure, particularly an automotive article for an electric vehicle, and more particularly a battery enclosure for the electric vehicle.

### CROSS-REFERENCE TO RELATED APPLICATIONS

This application claims the benefit of U.S. provisional patent application Ser. No. 63/380,897, filed Oct. 25, 2023, the entire disclosure of which is incorporated herein by reference.

### FIELD

The present disclosure relates to a composite article and method of forming, that provides electromagnetic interference (EMI) shielding of an enclosure, particularly an automotive article for an electric vehicle, and more particularly a battery enclosure for the electric vehicle.

### BACKGROUND

The growth of electric vehicles and the use of relatively large and heavy batteries has resulted in the need to provide newer types of battery enclosures. Among the goals of such enclosures are the ability to satisfy the necessary EMI shielding requirements along with fire, smoke, toxic fume generation consideration, which may occur particularly as a result of an accident. The battery enclosures also must desirably offer a relatively light-weight form that also retains the necessary structural requirements to enclose and support a battery within the vehicle.

### BRIEF DESCRIPTION OF THE DRAWINGS

The detailed description below may be better understood with reference to the accompanying figures which are provided for illustrative purposes and are not to be considered as limiting any aspect of the disclosure.

FIG. 1 is a cross-sectional perspective view of a mold and a sheet in a first position;

FIG. 2 is a cross-sectional side view of the mold and the sheet of FIG. 1;

FIG. 3 is a close-up cross-sectional side view of the mold and the sheet of FIG. 2;

FIG. 4 is a cross-sectional perspective view of the mold and the sheet of FIG. 1 in another position;

FIG. 5 is a cross-sectional side view of the mold and the sheet of FIG. 4;

FIG. 6 is a close-up cross-sectional side view of the mold and the sheet of FIG. 5;

FIG. 7 is a cross-sectional perspective view of the mold and the sheet of FIG. 1 in another position;

FIG. 8 is a cross-sectional side view of the mold and the sheet of FIG. 7;

FIG. 9 is a close-up cross-sectional side view of the mold and the sheet of FIG. 8;

FIG. 10 is a cross-sectional perspective view of the mold and the sheet of FIG. 1 in another position;

FIG. 11 is a close-up cross-sectional perspective view of the mold and the sheet of FIG. 10;

FIG. 12 is a cross-sectional side view of the mold and the sheet of FIG. 10;

FIG. 13 is a close-up cross-sectional side view of the mold and the sheet of FIG. 12;

FIG. 14 is a cross-sectional perspective view of the mold and the sheet of FIG. 1, in the position of FIG. 10, with a polymer composition partially filling a molding cavity of the mold;

FIG. 15 is a cross-sectional side view of the mold, the sheet and the polymer composition of FIG. 14;

FIG. 16 is a close-up cross-sectional side view of the mold, the sheet and the polymer composition of FIG. 15;

FIG. 17 is a cross-sectional perspective view of the mold and the sheet of FIG. 1, in the position of FIG. 10, with the polymer composition completely filling the molding cavity of the mold;

FIG. 18 is a cross-sectional side view of the mold, the sheet and the polymer composition of FIG. 17;

FIG. 19 is a close-up cross-sectional side view of the mold, the sheet and the polymer composition of FIG. 18;

FIG. 20 is a cross-sectional perspective view of the mold cavity side of the mold of FIG. 1 showing a retaining mechanism in an extended position;

FIG. 21 is a close-up cross-sectional perspective view of a portion of the retaining mechanism of FIG. 20 in the extended position;

FIG. 22 is a close-up cross-sectional side view of another portion of the retaining mechanism of FIG. 20 in the extended position;

FIG. 23 is a close-up cross-sectional perspective view of the portion of the retaining mechanism of FIG. 22;

FIG. 24 is a cross-sectional perspective view of the mold cavity side of the mold of FIG. 1;

FIG. 25 is a close-up cross-sectional perspective view of a portion of the retaining mechanism of FIG. 21 in the retracted position;

FIG. 26 is a cross-sectional side view of another mold and sheet in a first position;

FIG. 27 is cross-sectional side view of the mold and the sheet of FIG. 26 in another position;

FIG. 28 is a close-up cross-sectional side view of the mold and the sheet of FIG. 27;

FIG. 29 is a cross-sectional perspective view of another mold and sheet in a first position;

FIG. 30 is a cross-sectional side view of the mold and the sheet of FIG. 29;

FIG. 31 is a cross-sectional side view of the mold and the sheet of FIG. 29 in another position, with a polymer composition charge prior to compression molding;

FIG. 32 is a cross-sectional side view of the mold, the sheet and the charge of FIG. 31 in another position, with the polymer composition charge completely filling the molding cavity of the mold;

FIG. 33 is a close-up cross-sectional side view of the mold, the sheet and polymer composition of FIG. 32;

FIG. 34 is a cross-sectional side view of the mold, the sheet and the polymer composition of FIG. 32 in another position;

FIG. 35 is cross-sectional perspective view of the mold, the sheet and the polymer composition of FIG. 34; and FIG. 36 is close-up cross-sectional perspective view of the mold, the sheet and the polymer composition of FIG. 35.

### DETAILED DESCRIPTION OF PREFERRED EMBODIMENTS

It may be appreciated that the present disclosure is not limited in its application to the details of construction and the arrangement of components set forth in the following description or illustrated in the drawings. The embodiments herein may be capable of other embodiments and of being practiced or of being carried out in various ways. Also, it may be appreciated that the phraseology and terminology used herein is for the purpose of description and should not be regarded as limiting.

Electric vehicle (EV) batteries generate electromagnetic interference (EMI) which may be harmful to electronic systems/components of the vehicle, as well as may be susceptible to electromagnetic interference from other sources which may harm the batteries. The present disclosure provides a composite article (which also may be referred to as a part herein), preferably an enclosure within a vehicle, such as an EV battery enclosure and preferably formed of a polymer composition (e.g. thermoplastic or thermoset) composition with a molded-in sheet, preferably in the form of at least one metal sheet and more particularly at least one metal mesh sheet, which provides an EMI (electromagnetic interference) shield/shielding, which is sufficient for battery applications. For example, the metal sheet and/or the composite article with the metal sheet may provide a shielding effectiveness of at least a 20 decibel reduction over a range of 30 MHz to 1.5 GHz as measured according to ASTM D-4935-18. More preferably, the metal sheet may provide a shielding effectiveness of at least a 30 decibel reduction over a range of 30 MHz to 1.5 GHz as measured according to ASTM D-4935-18. Even more preferably, the metal sheet may provide a shielding effectiveness of at least a 40 decibel reduction over a range of 30 MHz to 1.5 GHz as measured according to ASTM D-4935-18. Also for example, the metal sheet may provide a shielding effectiveness of at least a 20 decibel reduction over a range 9 KHz to 15.9 MHz and at least a 50 decibel reduction over a range of 16 MHz to 18 GHz as measured according to IEEE 299-2006.

The formed composite article containing the metal sheet, preferably has a thickness in the range of 1.0 mm to 6.0 mm, more preferably 2.5 mm to 5.0 mm, including all individual values and increments therein. Accordingly, the formed composite article may have by way of example a thickness of 1.0 mm, 1.1 mm, 1.2 mm, 1.3 mm, 1.4 mm. 1.5 mm. 1.6 mm. 1.7 mm, 1.8 mm, 1.9 mm, 2.0 mm, 2.1. mm, 2.2 mm, 2.3 mm, 2.4 mm, 2.5 mm, 2.6 mm, 2.7 mm, 2.8 mm, 2.9 mm, 3.0 mm, 3.1 mm, 3.2 mm, 3.3 mm, 3.4 mm, 3.5 mm, 3.6 mm, 3.7 mm, 3.8 mm, 3.9 mm, 4.0 mm, 4.1 mm, 4.2 mm, 4.3 mm, 4.4 mm, 4.5 mm, 4.6 mm, 4.7 mm, 4.8 mm, 4.9 mm, 5.0 mm, 5.1 mm, 5.2 mm, 5.3 mm, 5.4 mm, 5.5 mm, 5.6 mm, 5.7 mm, 5.8 mm, 5.9 mm or 6.0 mm. As discussed more fully herein, in the composite article that is formed, all or a majority portion of the metal sheet is now selectively located at one side of such article.

The sheet, and more particularly the at least one metal sheet or the at least one metal mesh sheet, preferably has a thickness of 0.01 mm to 0.50 mm, including all individual values and increments therein, when present in the composite article. Accordingly, the one at least one metal sheet, which may be in the form of metal mesh, may have by way of example a thickness of 0.01 mm, 0.02 mm, 0.03 mm, 0.04 mm, 0.05 mm, 0.06 mm, 0.07 mm, 0.08 mm. 0.09 mm, 0.1 mm, 0.2 mm. 0.3 mm, 0.4 mm or 0.50 mm. The metal sheet, and more particularly the metal mesh sheet, may be made of steel, aluminum, copper, nickel, iron, or metal alloys. More particularly, the metal sheet, and more particularly the metal mesh sheet may essentially consist of or consist of metal. The metal sheet, and more particularly the metal mesh, can be coated with another metal (e.g. metal plating such as silver plating, copper plating or nickel plating) or a polymer composition or a corrosion-resistant coating. The metal sheet, and more particularly the metal mesh, can also be coated with a flame retardant, such as an intumescent flame retardant. The metal mesh sheet itself may preferably be in the form of a woven or non-woven type mesh configuration. The metal mesh sheet may preferably have a mesh size in the range of 40 mesh/inch to 300 mesh/inch including all values and increments therein. More specific examples include an aluminum mesh with an adhesive such as a glass fiber adhesive; an aluminum mesh with a polyester/polyethylene film coating; and a multi-layer sheet comprising fabric (e.g. non-metal woven) layer and a metal layer.

The polymer composition may preferably contain one or more additives, such as graphite, graphene, metal whiskers, carbon black, or a metal oxide, such as iron oxide. It is also contemplated that the polymer composition contains ferrites, which preferably include iron oxide (Fe₂O₃) or magnesium ferrite (MgFe₂O₄) or zinc ferrite (ZnₓFe₃₋ₓO₄, e.g., ZnFe₂O₄)) or magnesium zinc ferrite (MgZnFe₂O₄). The polymer composition may also preferably contain one or more flame retardants, preferably an intumescent type flame retardant, and in particular, non-halogenated flame intumescent flame retardant (IFR), as well as glass fillers, such as glass fibers. Such IFRs preferably contain an acid source, a carbonaceous charring agent, and a foaming agent. The acid source can be one of phosphoric acid, sulfuric acid, or boric acid. The carbonizing source may include pentaerythritol, sorbitol, mannitol, dextrins, starch, pheol-formaldehyde resins, and char-forming polymers. The foaming source is typically nitrogen containing compounds, such as urea, urea-formaldehyde resin, melamine, dicyandiamide, and polyamides. The flame retardants preferably include the flame retardants disclosed in U.S. Publ. No. 2019/0264002 entitled Flame Retardant Propylene Composition.

The polymer composition may also preferably contain one or more foaming agents, including a physical foaming agent or chemical foaming agent, to reduce the final article density.

It is also contemplated that one may utilize, in lieu of the above-referenced metal sheet, one or more polymer composite sheets already containing metal (e.g. a metal sheet; metal mesh; metal particulate dispersed in a polymer composition) and/or other additives to similarly provide EMI shielding. The one or more polymer composite sheets containing metal and providing EMI shielding preferably has a thickness of 0.05 mm to 0.50 mm, including all individual values and increments therein, when present in the composite article. More preferably the polymer composite sheet containing metal and providing EMI shielding has a thickness of 0.50 mm to 1.5 mm, including all individual values and increments therein. The one or more polymer composite sheets containing metal may be formed by, e.g., extrusion of a metal particulate (discontinuous phase) disposed in a polymer matrix (continuous phase).

The use of at least one polymer composite sheet containing metal and/or the composite article itself containing at least one polymer composite sheet containing metal, are also contemplated to provide a shielding effectiveness of at least a 20 decibel reduction over a range of 30 MHz to 1.5 GHz as measured according to ASTM D-4935-18. More preferably, the polymer composite sheets containing metal may provide a shielding effectiveness of at least a 30 decibel reduction over a range of 30 MHz to 1.5 GHz as measured according to ASTM D-4935-18. Even more preferably, the metal sheet may provide a shielding effectiveness of at least a 40 decibel reduction over a range of 30 MHz to 1.5 GHz as measured according to ASTM D-4935-18. Also for example, the metal sheet may provide a shielding effectiveness of at least a 20 decibel reduction over a range 9 KHz to 15.9 MHz and at least a 50 decibel reduction over a range of 16 MHz to 18 GHz as measured according to IEEE 299-2006.

The additives that may be relied upon in such polymer composite sheets to similarly augment EMI shielding include, but are not limited to graphene, graphite, metal whiskers, carbon black or a metal oxide, such as iron oxide. One may also again include a ferrite. The formed article containing the polymer composite sheet containing metal sheet, and more particularly the metal mesh, or other additives to similarly provide EMI shielding, may have a thickness in the range of 2.0 mm to 7.0 mm, including all individual values and increments therein.

The formed article containing the polymer composite sheet is contemplated herein to provide a relatively light weight article in comparison to the use of metal sheet on its own. The formed article containing the polymer composite sheet also preferably includes flamability protection, particularly to delay exposure of direct flame to vehicle occupants.

As alluded to above, preferably, non-halogenated intumescent flame retardants and/or carbon fibers/fillers are included in the polymer composition to allow for formation of a protective char layer. The level of such non-halogenated intumescent flame retardants preferably falls in the range of 20.0% (wt.) to 50.0 % (wt.), including all individual values and increments therein. That is, such preferred intumescent flame retardants can assist in providing a delayed thermal response from exposure to flames. The article formed herein may also provide the benefit of thermal insulation and preferably eliminate need of a separately formed thermal blanket to improve isolation of, e.g., a battery enclosure.

Additionally, as a result of the forming/molding process, described more fully herein, the sheet may be disposed at the B-side/surface of the article, which is the side/surface that is then in contact with or faces another component, such as the battery within a battery enclosure. That is, the sheet may be selectively located more towards the B-side/surface of the article than towards the A-side/surface. Preferably a majority portion of the sheet, or 60% or more of the sheet, can now be selectively located more towards the B-side/surface of the article than towards the A-side/surface. Accordingly, 60% (a majority portion) to 100% (all) of the sheet may be selectively located more towards the B-side/surface of the article than towards the A-side/surface, including all individual values and increments therein. As a result, the article preferably indicates an electrically conductive surface (e.g. electrically isolated mesh) at the B-side/surface, while the A-side/surface remains electrically non-conductive. It should be appreciated that the A-side/surface of the article may be understood as a first, or outer, side/surface and the B-side/surface of the article may be understood as a second, or inner, side/surface. This selective location of the sheet, and more particularly the metal sheet, then improves safety (e.g. electrical isolation) for the EV battery enclosure.

Alternatively, it should be understood that the present disclosure provides that the sheet may also be disposed at the A-side of the article, as not to be limited by having to be disposed at the B-side of the article, which also provides EMI shielding. That is, the sheet may be selectively located more towards the A-side/surface of the article than towards the B-side/surface. Preferably a majority portion of the sheet, or 60% or more of the sheet, can now be selectively located more towards the A-side/surface of the article than towards the B-side/surface. Accordingly, 60% (a majority portion) to 100% (all) of the sheet may be selectively located more towards the A-side/surface of the article than towards the B-side/surface, including all individual values and increments therein.

During forming of the article, a thermoplastic injection mold may be employed to process the polymer composition, which also now is preferably configured to provide position and tension control of the sheet within the molding cavity. In the broad context of the present invention, one may therefore utilize injection molding, injection-compression molding, compression molding, or thermoforming.

The position and tension control of the sheet may preferably be accomplished during closing of the mold, as well as during injection of the polymer composition into the molding cavity. The position and tension control may preferably be supplied by a holding (e.g. clamping) mechanism which holds/clamps or otherwise retains the sheet preferably around an entire periphery of the sheet. It may also be accomplished by the use of robotic grippers. In particular, by preferably holding/clamping the sheet outside the molding cavity, such tensioning provides for relatively unconstrained sheet movement within the molding cavity during injection of the polymer composition at which time the flow and downward pressure of the polymer composition stretches and forms the sheet into the contour of the A-side/surface or B-side/surface of the mold, whichever is desired.

The controlled holding/clamping of the sheet is also provided to manage the integrity of the sheet, particularly to reduce and/or inhibit ripping, tearing, wrinkling, folding or other damage to the sheet throughout the article during closing of the mold and during injection of the polymer composition into the molding cavity. Accordingly, the sheet is tensioned in a manner that retains the sheet but which will preferably allow for some release or slipping from the selected tensioning so that the sheet can be drawn into the mold cavity. In such regards, the sheet is preferably held/clamped as to provide a relatively flat and flush mounting flange surface at the parting line of the injection mold, particularly without gaps which may otherwise create EMI leakage and degrade the shielding performance, for the purpose of continuity and grounding of the cover to base interface for the EV enclosure.

In other preferred embodiments, the planar sheet, solely as a metal sheet or as polymer composite sheet containing metal (that provides EMI shielding) may be pre-formed into a three-dimensional shape, such as by being thermoformed, including either negative pressure (vacuum) formed or positive pressure formed, prior to being placed in the injection, injection-compression or compression mold.

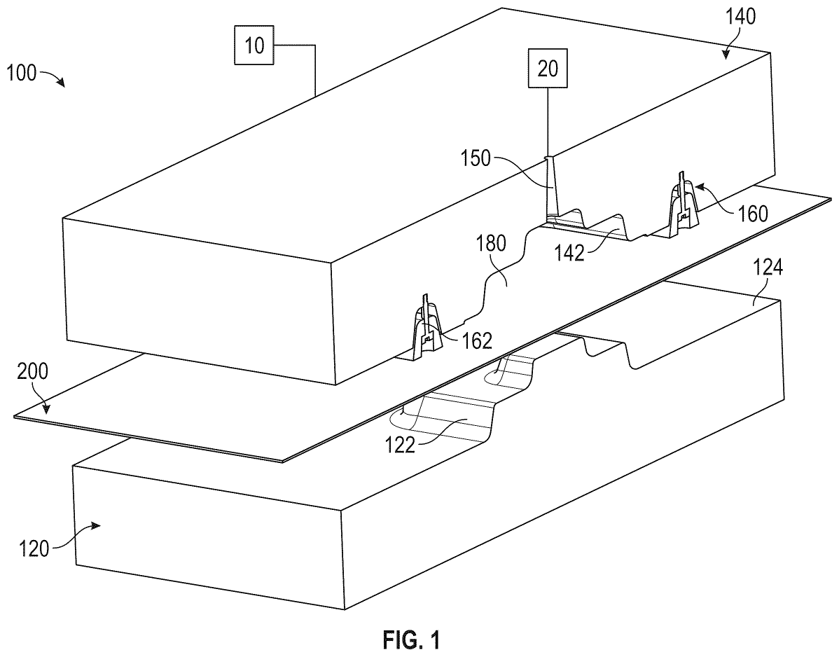

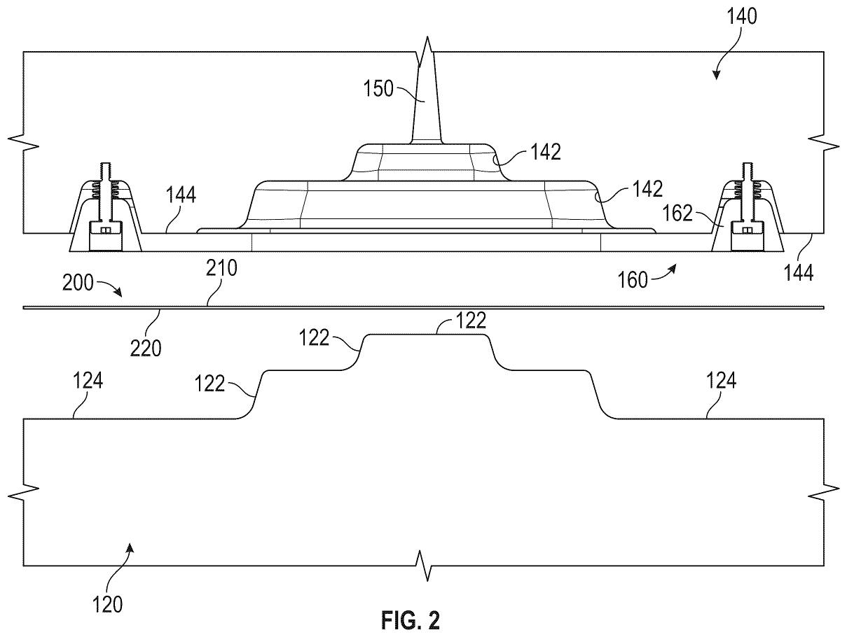

Referring now to FIGS. 1-3, a longitudinal cross-sectional view of a mold 100 is shown, particularly an injection mold to inject a polymer composition when the mold is in a fully closed state, or which may also be used as an injection-compression mold, to inject the polymer composition when the mold is in an open state (i.e. not fully closed) at a beginning of the molding process, to from an article according to the present disclosure. As shown the mold 100 may reside in a mold press 10 and be arranged as to have a horizontal parting line between the mold halves, i.e. the mold core side 120 and mold cavity side 140.

As shown, the mold 100 comprises a mold core side 120 (which may also be referred to as the core half or first half) having a core side molding surface 122, as well as a mold cavity side 140 (which may also be referred to as the cavity half or second half) having a cavity side molding surface 142. The core side molding surface 122 and the cavity side molding surface 142 and disposed on opposite sides of the mold facing one another and define a molding cavity 180 therebetween.

As shown, the mold cavity side 140 may further include at least one injection port 150 through which a molten thermoplastic composition may be injected from injection unit 20 (e.g. reciprocating screw injection unit) and received into the molding cavity 180. Also as shown, the mold cavity side 140 further comprises a spring-loaded retaining (sheet retention) mechanism 160, comprising a clamp ring 162, shown as a closed loop, the operation of which is explained in greater detail below.

As shown by FIGS. 1-3, disposed between the mold core side 120 and the mold cavity side 140, and more particularly, the core side molding surface 122 and the cavity side molding surface 142 is a relatively planar sheet 200, which may more preferably be a planar metal sheet, and more particularly the metal mesh sheet. As shown, the planar sheet 200 is not yet in contact with either the mold core side 120 or the mold cavity side 140.

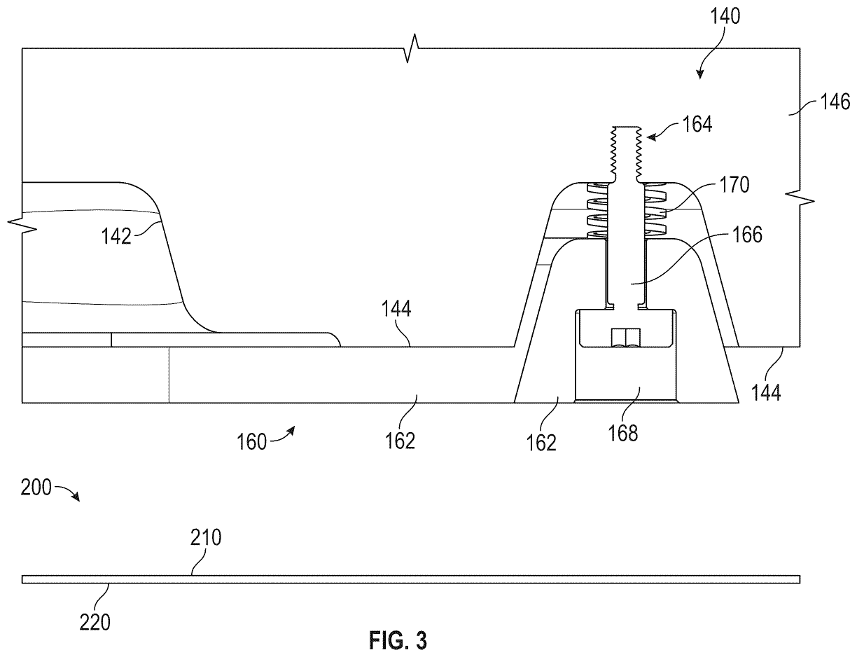

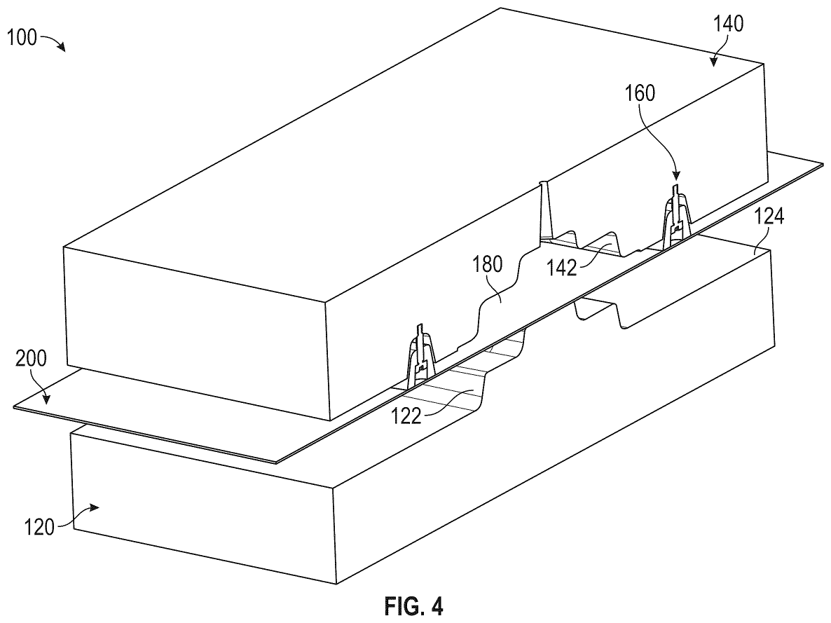

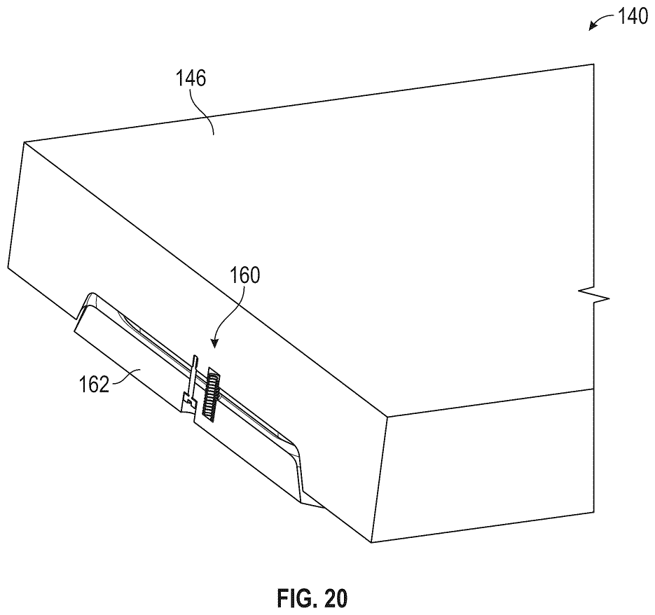

As shown by FIG. 3 (as well as FIGS. 20-25 for alternative views), the retaining mechanism 160 comprises a closed loop clamp ring 162, which is attached to the cavity side mold block 146 by threaded fasteners 164, particularly threaded shoulder bolts threaded into the cavity side mold block 146. As shown, the retaining mechanism 160 further comprises a bias member 170, preferably a helical compression spring, disposed adjacent the threaded fastener 164 (FIGS. 20-25 for additional views). With respect to operation, the compression spring 170 biases/forces the clamp ring 162 to/towards an extended position as shown. In certain views, the threaded fasteners 164 and a bias members 170 are not shown to eliminate complexity and increase clarity.

As shown by FIGS. 1-3, disposed between the mold core side 120 and the mold cavity side 140, and more particularly, the core side molding surface 122 and the cavity side molding surface 142 is a relatively planar sheet 200, which may more preferably be a metal sheet, and more particularly the metal mesh sheet. As shown, sheet 200 has a first side 210 and a second side 220 (opposite the first side 210) and is completely planar.

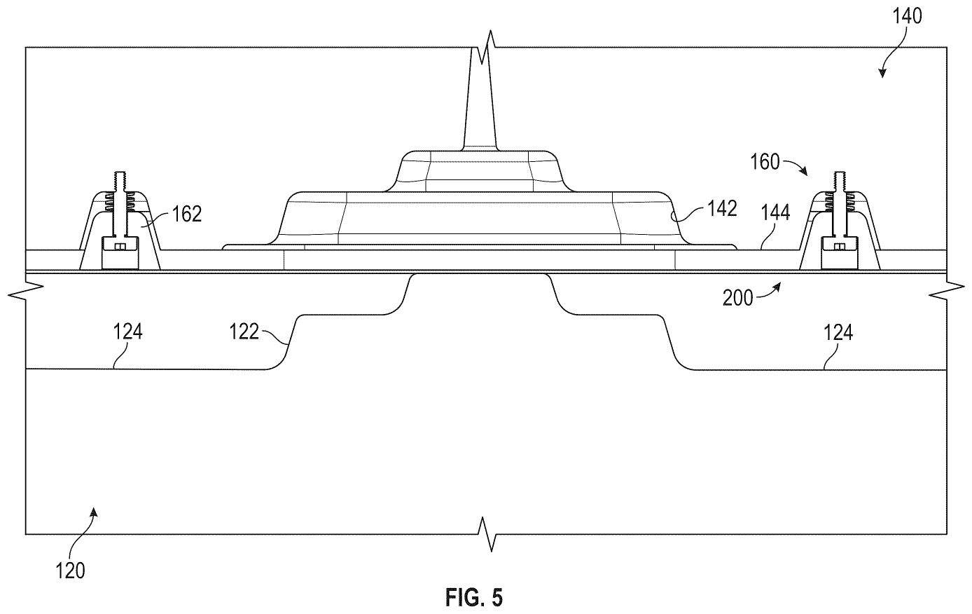

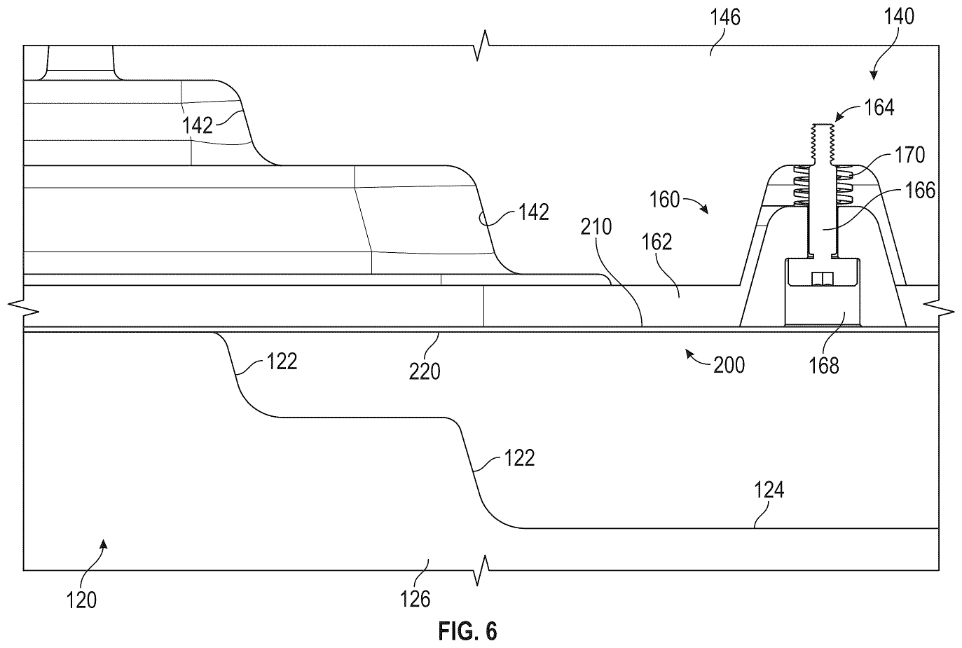

Referring now to FIGS. 4-6, the mold 100 has been partially closed such that the first side 210 of the sheet 200, still in relatively planar form, is now in contact with the clamp ring 162, and the second side 220 of the sheet 200 is now in contact with the core side molding surface 122. As shown, the clamp ring 162 is still in the extended position.

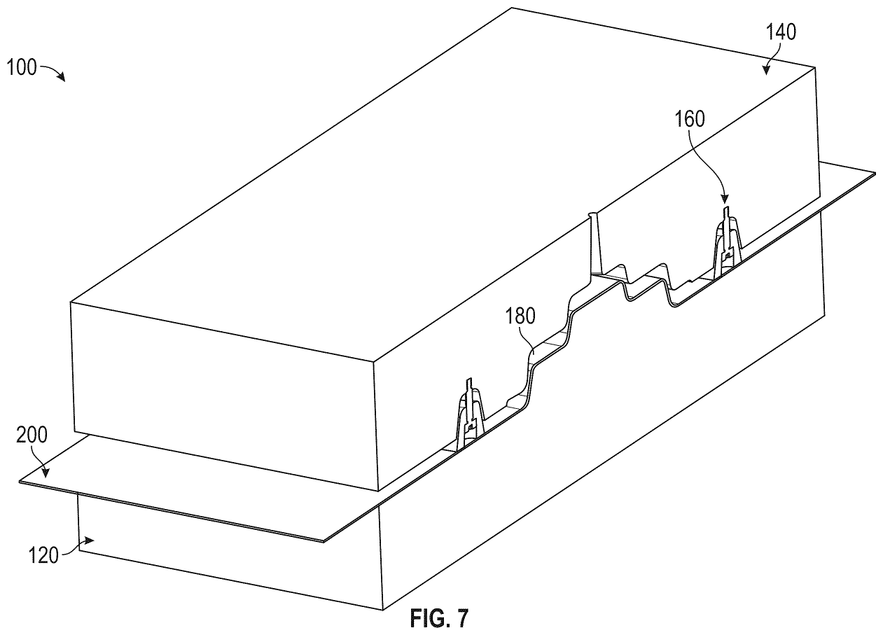

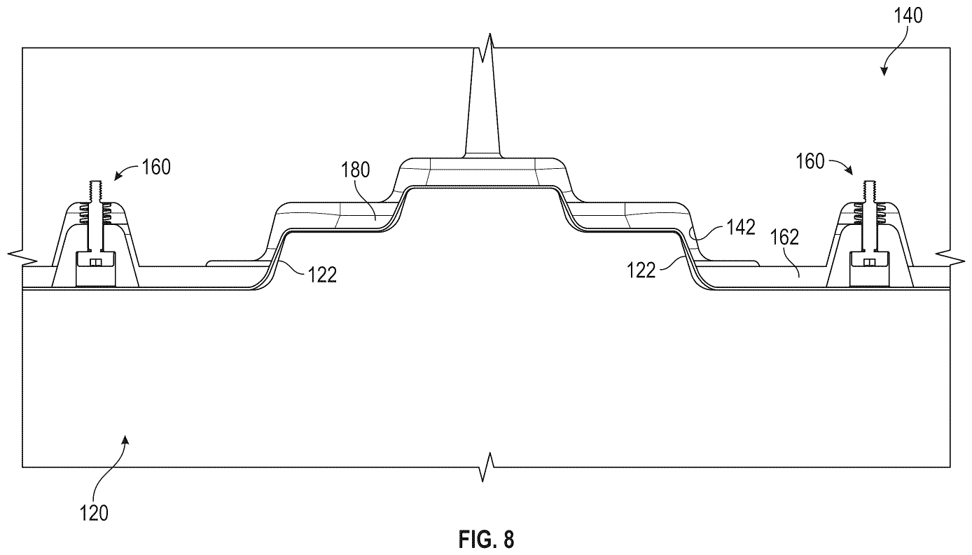

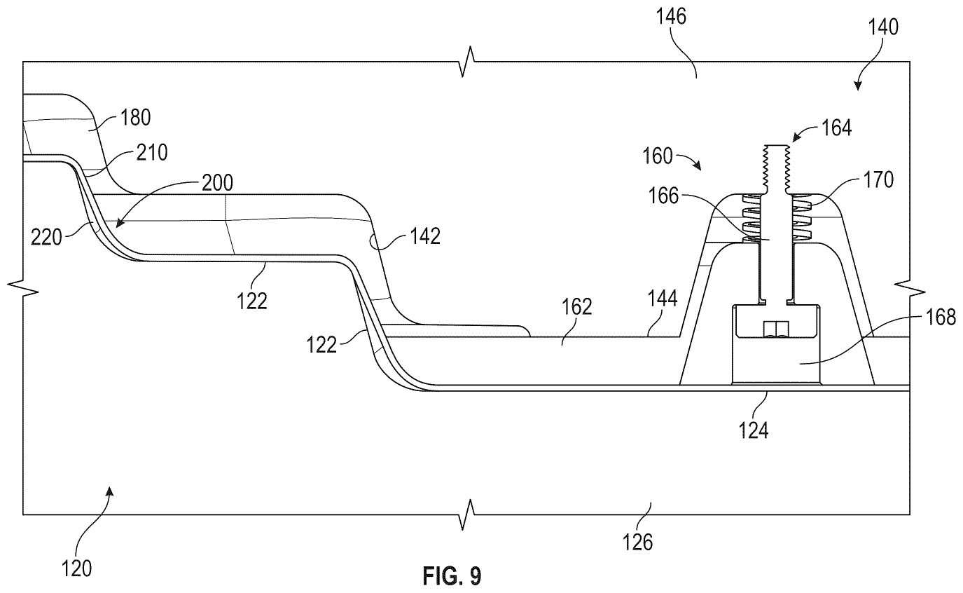

Referring now to FIGS. 7-9, the mold 100 has been further closed such that the sheet 200 has been drawn and deformed into a three-dimensional form/shape, particularly as a result of being formed over the core side molding surface 122. As shown, the first side 210 of the sheet 200 is still in contact with the clamp ring 162, and the second side 220 of the sheet 200 is still in contact with the core side molding surface 122. Additionally, the second side 220 of the sheet 200 is now also in contact with the core side runoff surface 124. As such, the sheet 200 is now initially clamped between the clamp ring 162 and the core side runoff surface 124, particularly due to a clamping force being provided as a result of partially retraction of the clamp ring 162 and associated compression of the spring 170.

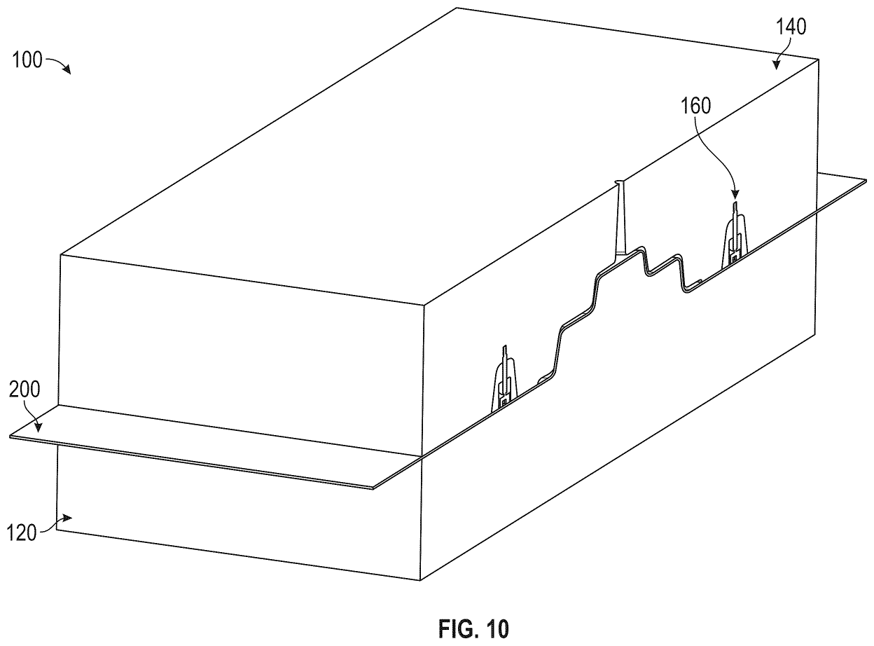

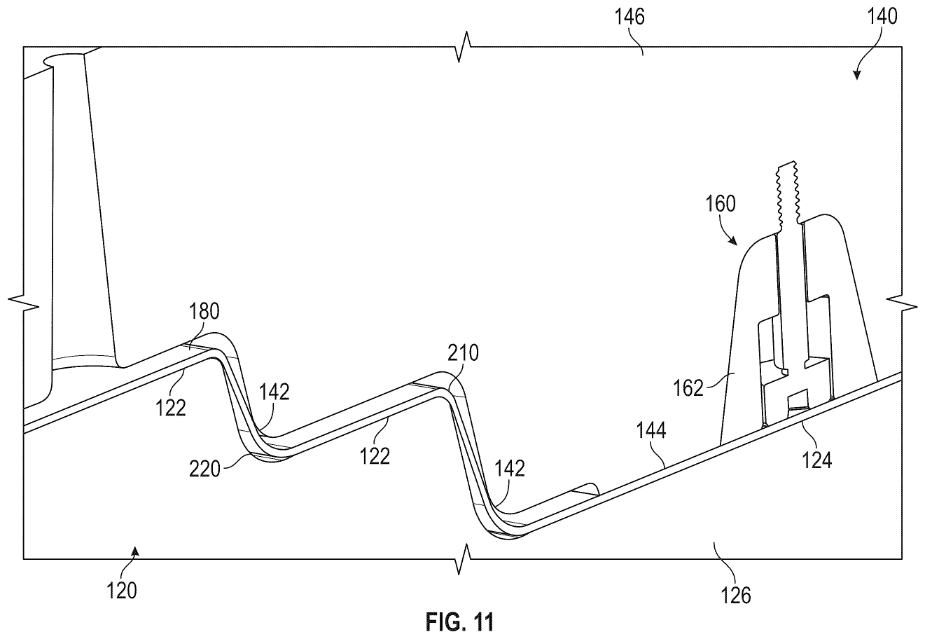

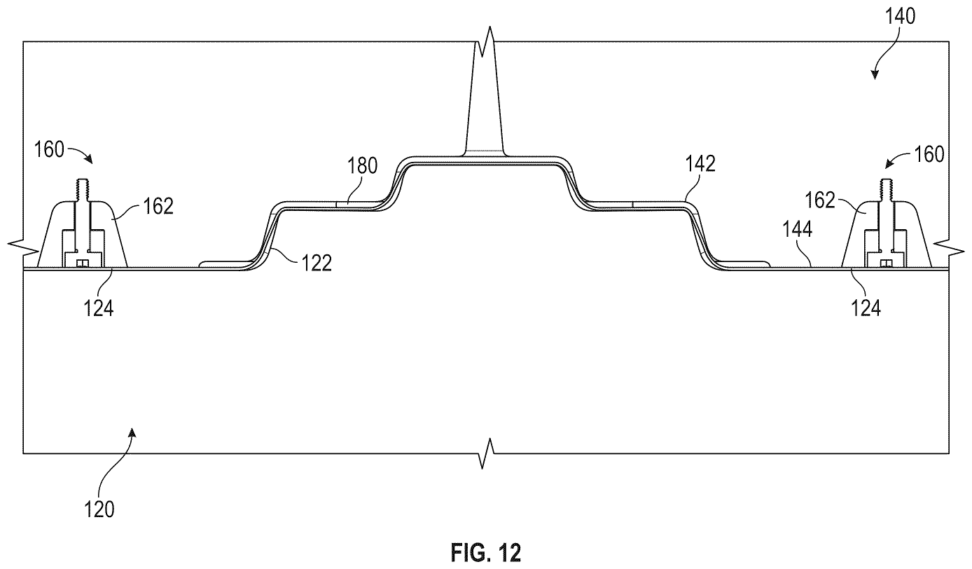

Referring now to FIGS. 10-12, the mold 100 is now at full closure. As shown, the sheet 200 is further clamped between the clamp ring 162 and the core side runoff surface 124, particularly with greater clamping force due to full retraction of the clamp ring 162 and associated further compression of the spring 170.

As shown, the second side 220 of the sheet 200 is still in contact with the core side molding surface 122. Additionally, however, the first side 210 of the sheet 200 may now be in contact in certain locations with the cavity side molding surface 142.

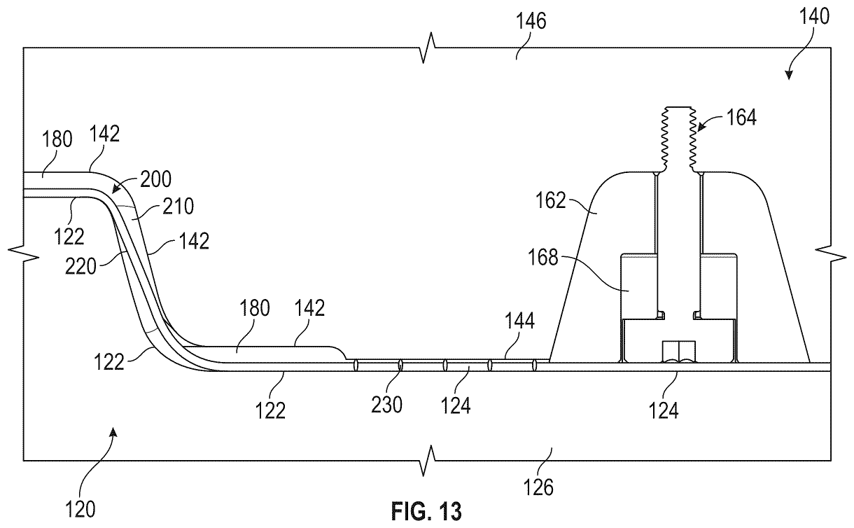

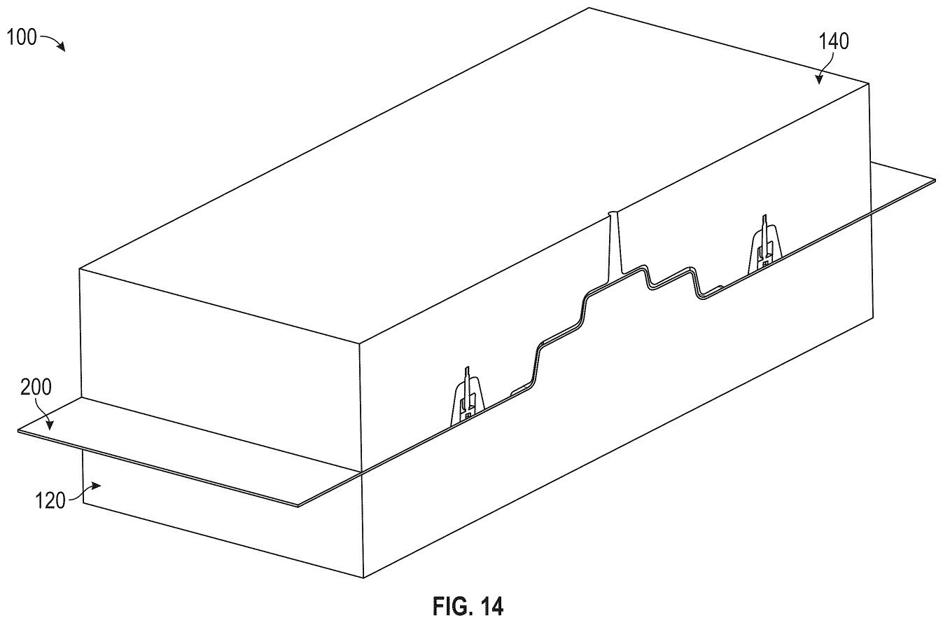

Referring now to FIG. 13 as a further close-up view of mold 100, in an alternative embodiment, the sheet 200 may more preferably include a plurality of through-openings 230, which may be referred to as stress/strain relief slits to allow the sheet 200 to be more efficiently drawn into the molding cavity 180 during three-dimensional forming, as well as injection molding. Moreover, the cavity side runoff surface 144 between the molding cavity 180 and the clamp ring 162 may preferably be configured as to not make contact with the first side 210 of the sheet 200 (e.g. by 0.050 mm or less) to better enable the sheet 200 to be drawn into the into the molding cavity 180 during three-dimensional forming, as well as injection molding.

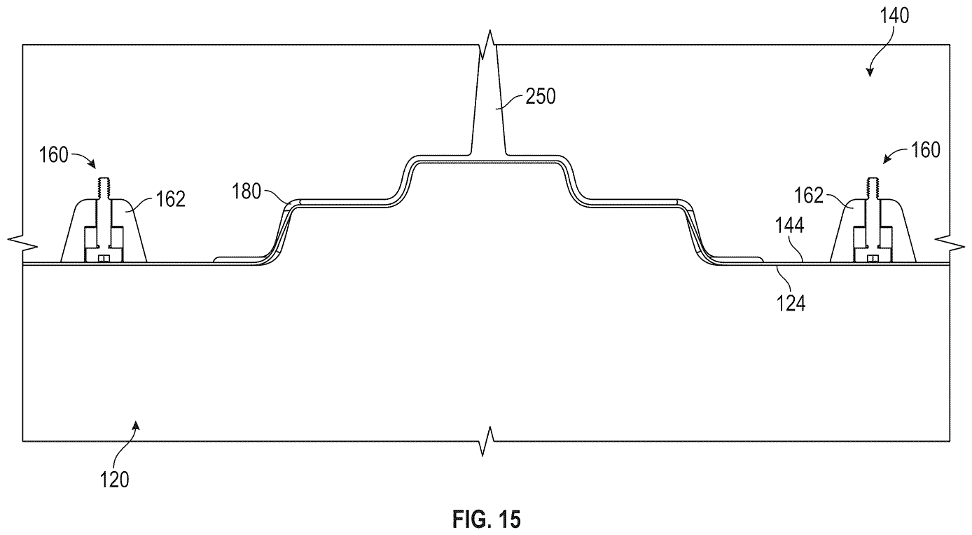

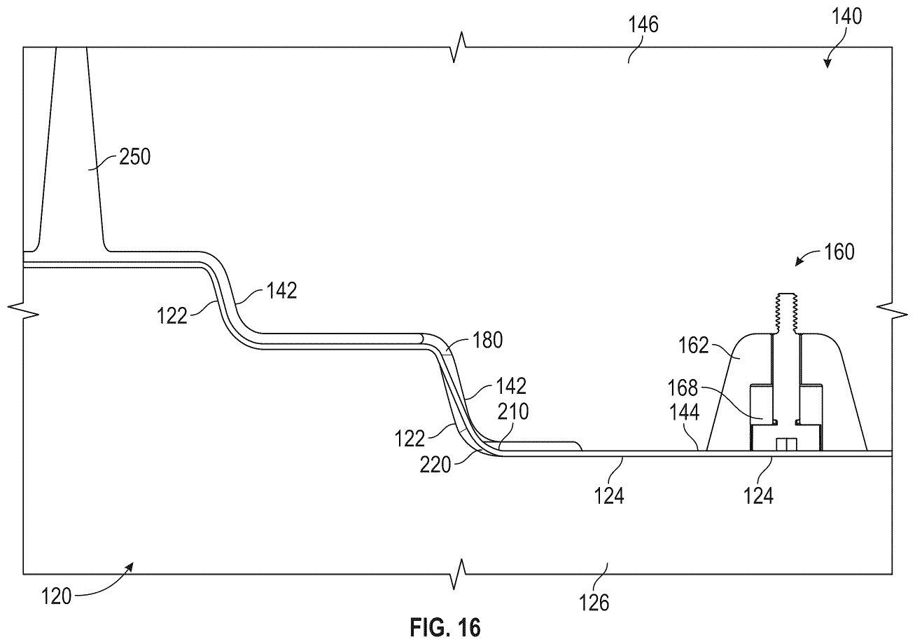

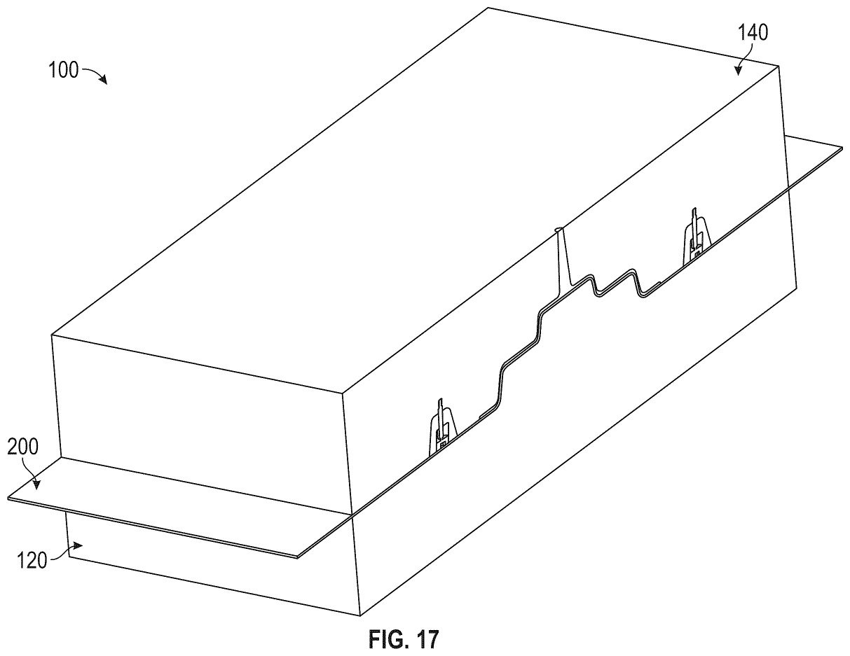

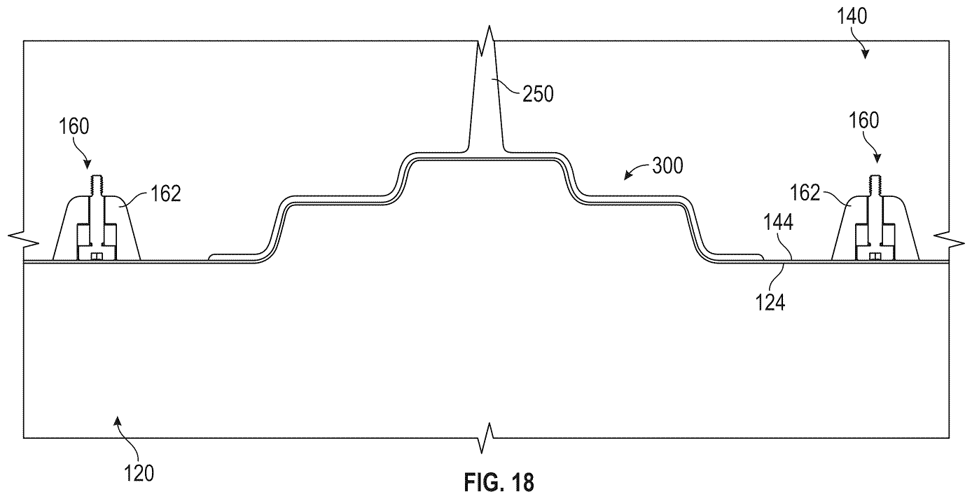

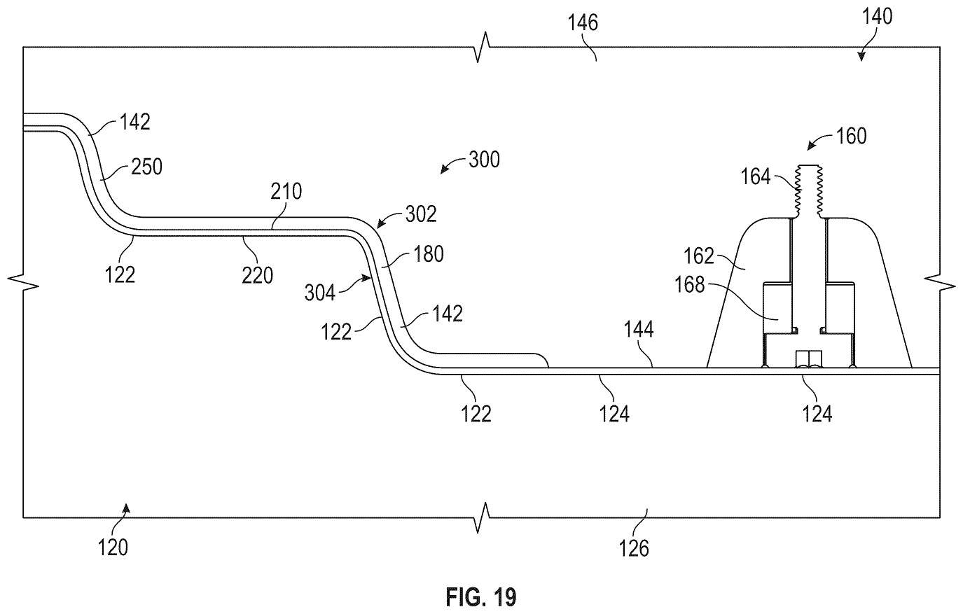

Referring now to FIGS. 14-19, FIGS. 14-16 and FIGS. 17-19 show a progression of a molten polymer composition 250 flowing through the molding cavity 180 while the mold 100 is at full closure. As shown, as a result of the flow of the polymer composition 250 and the molding pressures (such as due to clamp tonnage and packing pressure) associated therewith, the sheet 200 is further deformed, particularly away from contact with the cavity side molding surface 142. FIGS. 17-19 show the fully formed article 300. As can be observed, the sheet 200 is now preferably disposed at one side of the polymer composition 250 and article 300. More particularly, article 300 has an A-side/surface 302 and a B-side/surface 304, with the sheet 200 disposed at the B-side/surface 304.

Expanding on the above, the sheet 200 is now selectively located towards one side of the article 300 that is produced, namely the side of the article 300 away from the location for injection of the polymer composition 250, such as away from or opposite the injection port 150. More specifically, 60% or more of the sheet 200 is now selectively located towards one side of the article 300 that is produced, namely the side of the article 300 generally away from or opposite the injection port 150 where the polymer composition 250 is introduced into the molding cavity 180. Such flow of the polymer composition 250 under pressure causes the sheet 200 to locate to another side of the mold 100.

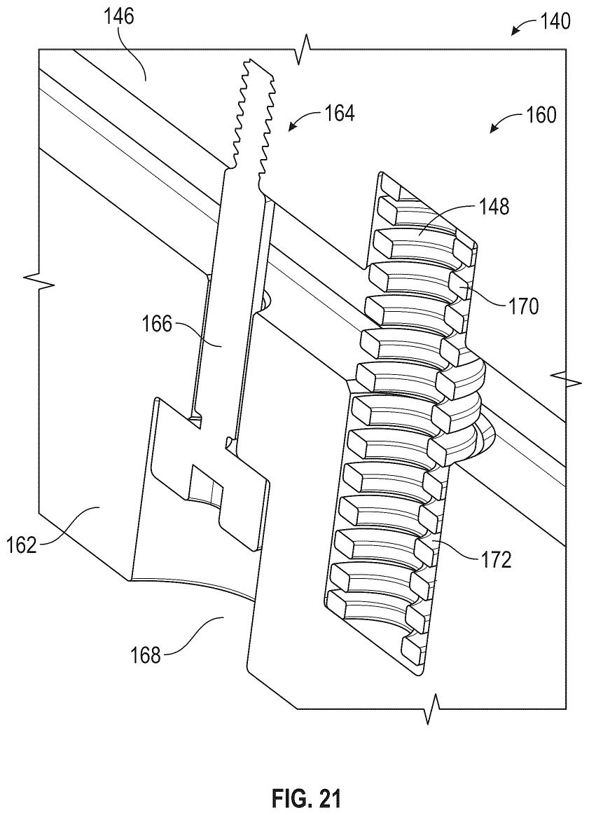

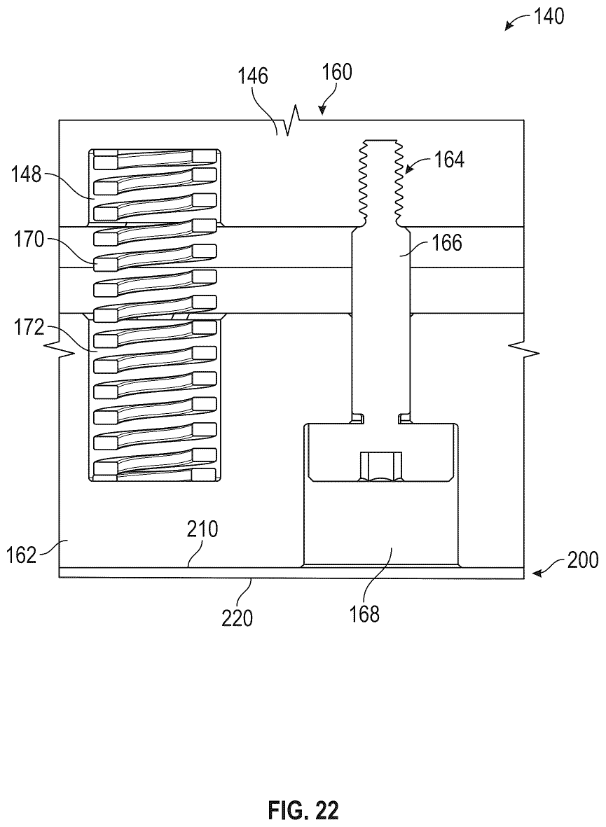

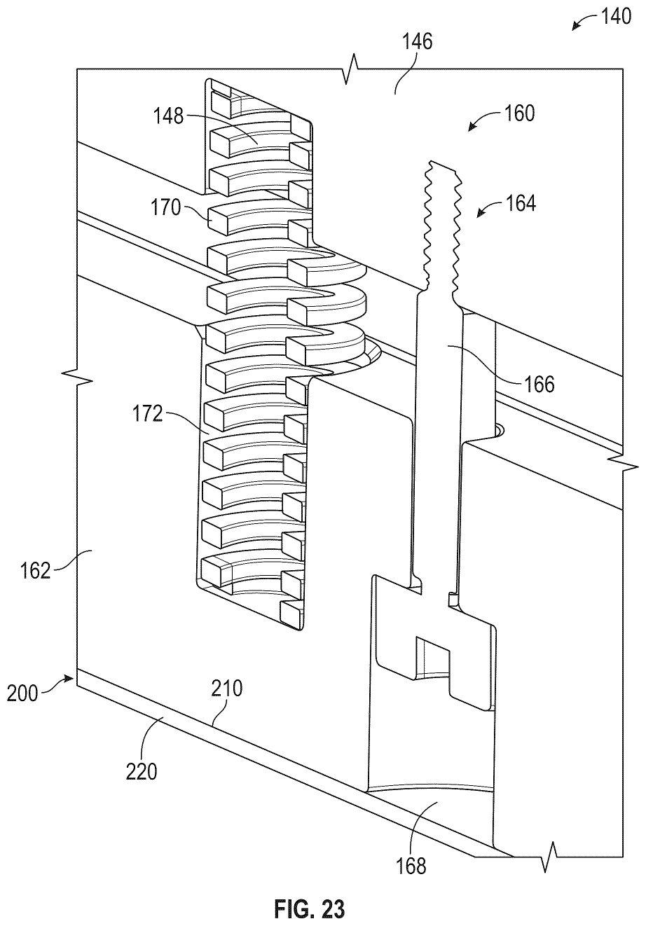

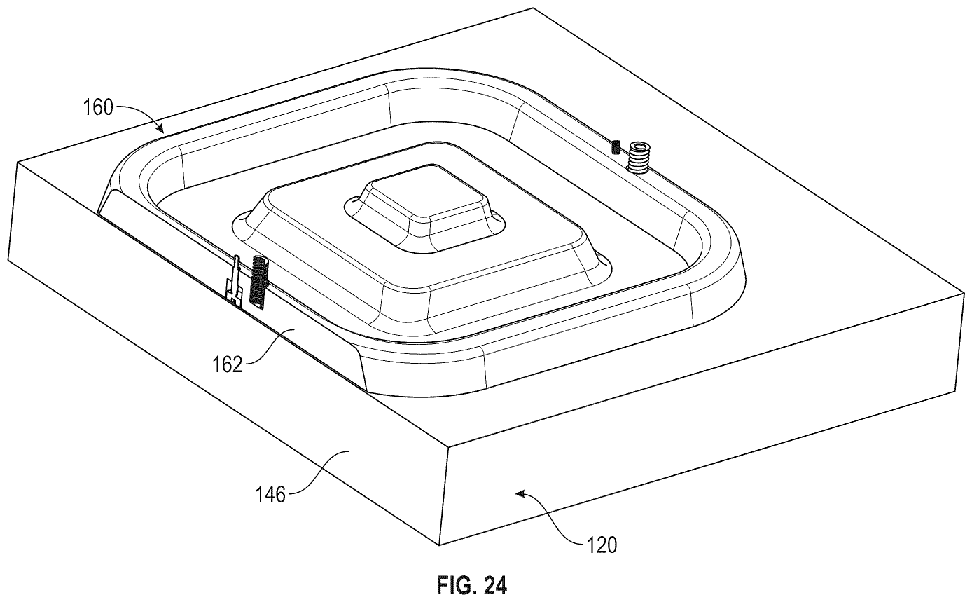

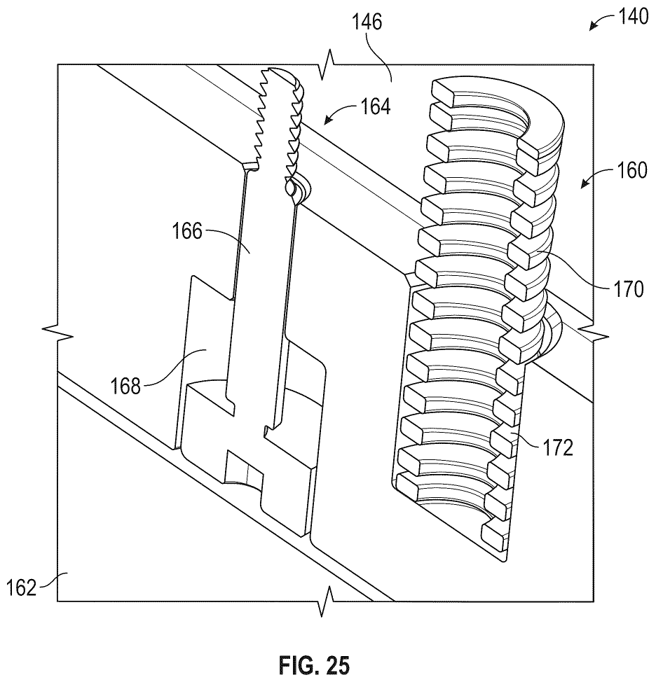

Referring now to FIGS. 20-25 there is shown the mold cavity side 140 with additional views of the spring-loaded retaining mechanism 160. More particularly, FIGS. 20-23 show the spring loaded retaining mechanism 160 in the extended position, without the sheet 200 in FIGS. 20-21 and with the sheet in FIGS. 22-23. As shown, the shaft 166 of the shoulder bolt 164 extends through a counterbore 168 in the clamp ring 162, while the spring 170 is disposed in a cylindrical recess 148 in the cavity side mold block 146, and a cylindrical recess 172 in the clamp ring 162. FIGS. 24-25 show the spring-loaded retaining mechanism 160 in the retracted position. It should be understood that the shoulder bolt 164 and spring 170 are shown at only two locations for clarity, and further shoulder bolts 164 and springs 170 are disposed around a periphery of the clamp ring 162 to provide to provide an equally distributed load and alignment.

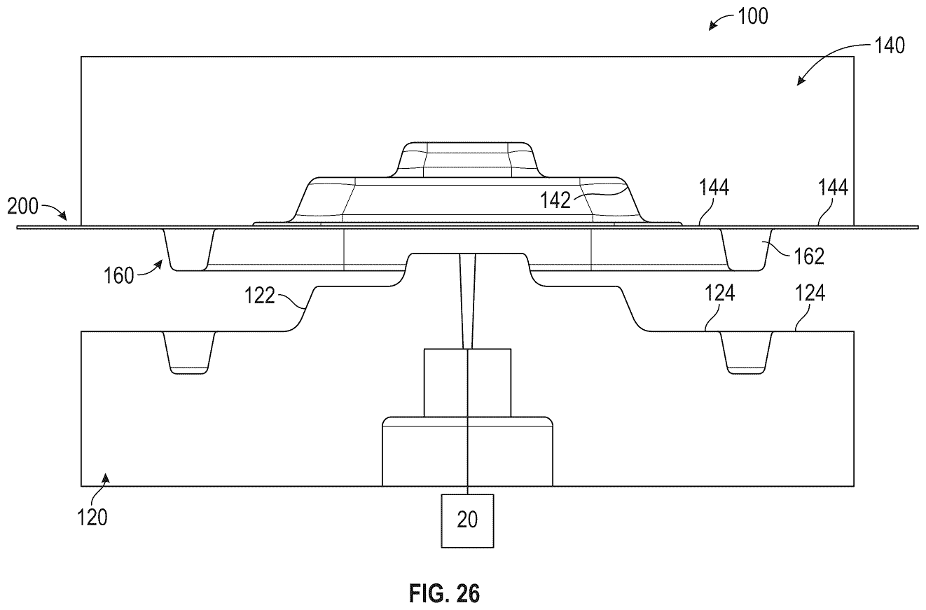

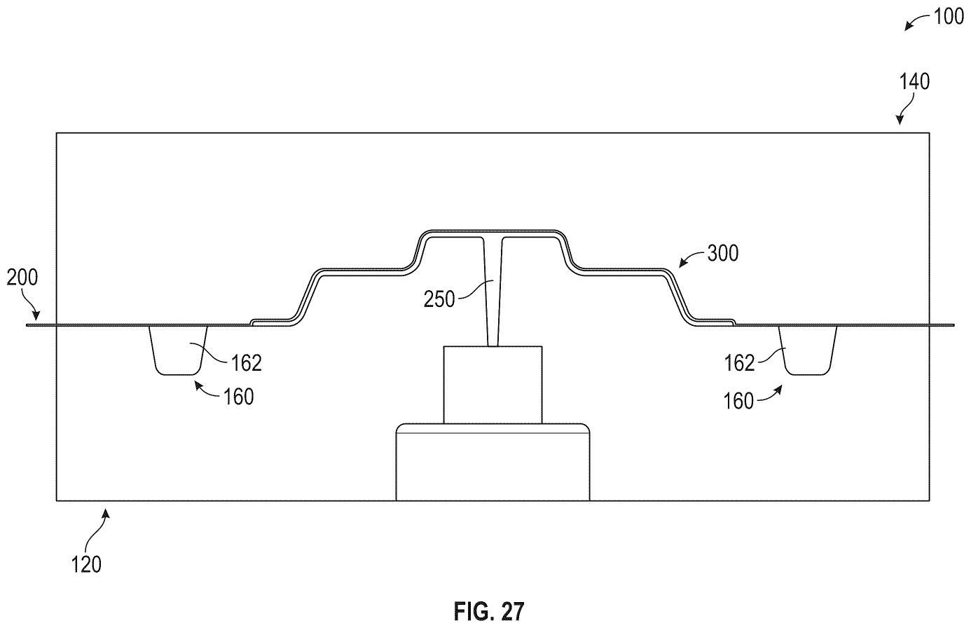

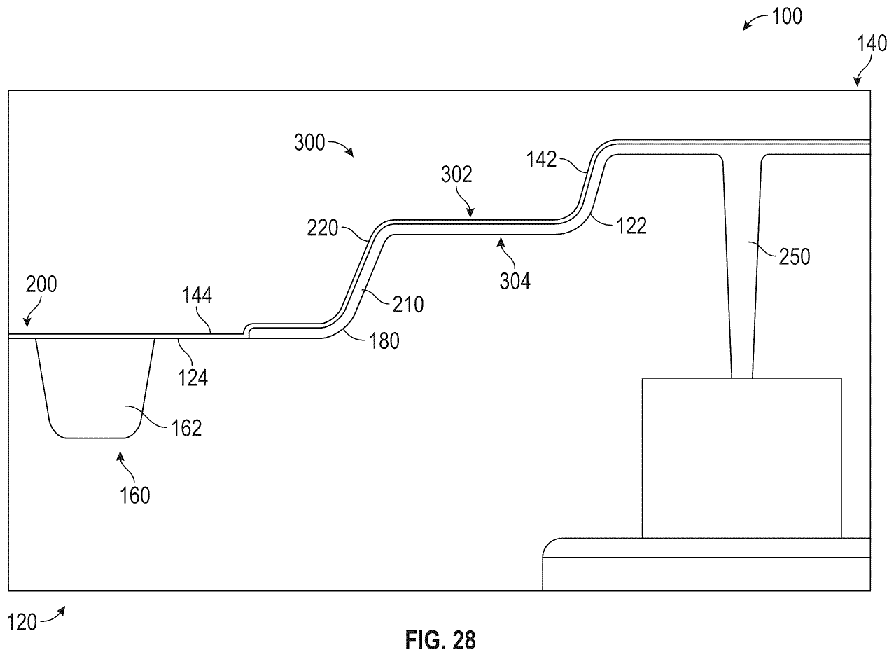

Referring to FIGS. 26-28, in other variants, the mold core side 120 may include the injection port 150 through which the molten thermoplastic composition 250 may be injected from injection unit 20 and received into the molding cavity 180. Also as shown, the mold core side 120 may further comprise the retaining mechanism 160, comprising a clamp ring 162, the operation of which is explained in greater detail above. However, similar to the mold 100 above, the mold 100 is arranged with the mold cavity side 140 overlying the mold core side 120.

When the mold 120 as shown in FIGS. 26-28 is arranged in mold press 10 such that the parting line between the mold core side 120 and the mold cavity side 140 is horizontal, having the retaining mechanism 160 disposed on the mold core side 120 permits the sheet 200 to be supported (against gravity) by the retaining mechanism 160 prior to mold closure. Moreover, the polymer composition 250 may be introduced through injection port 150 before the sheet 200 is deformed by closing the mold 150, or otherwise deformed by closing the mold 100 but before the mold 100 reaches full (complete) closure. In the foregoing manner, the molten polymer composition 250 may spread in a form of a disc on the core side molding surface 122 prior to full closure of the mold 150, which may make filling of the molding cavity 180 with lower pressures.

Alternatively, while the injection port 150 and retaining mechanism are disclosed as being on either the mold core side 120 or the mold cavity side 140, it should be understood that the injection port 150 and the retaining mechanism 160 may be disposed on opposite sides of the mold 100. For example, the injection port 150 may be disposed on the mold core side 120 and the retaining mechanism 160 may be disposed on the mold cavity side 140, or the injection port 150 may be disposed on the mold cavity side 140 and the retaining mechanism may be disposed on the mold core side 120.

As such, with the mold 100 of FIGS. 26-28, the article 300 similarly has an A-side/surface 302 and a B-side/surface 304, but with the sheet 200 disposed at the A-side/surface 302.

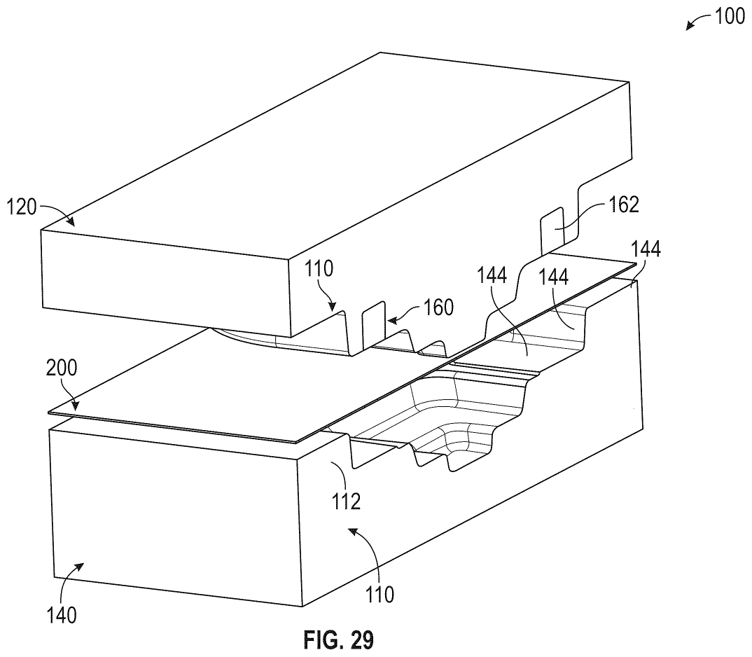

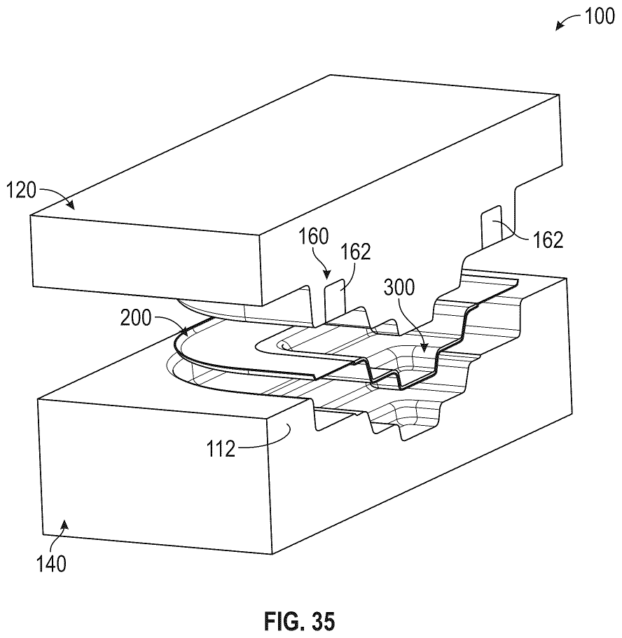

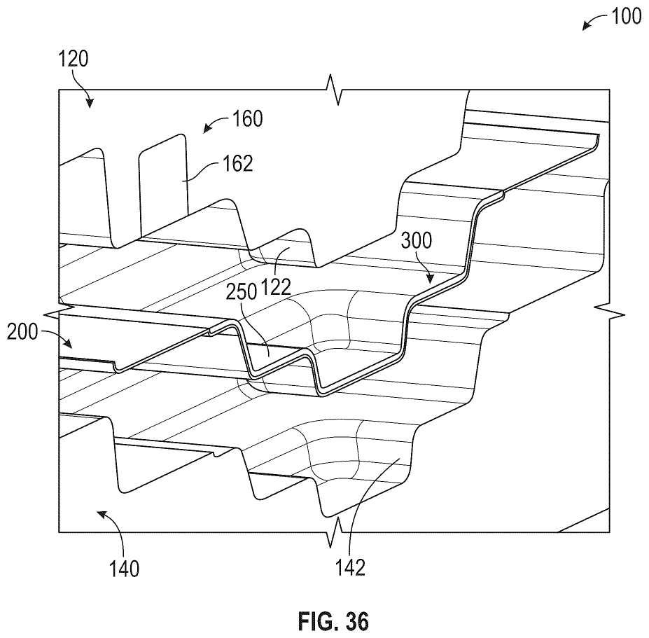

Referring to FIGS. 29-36, in other variants, the mold 100 may not include an injection port 150. As shown, the mold 100 may be a compression mold as opposed to an injection mold. However, in other variants, the mold 100 may include the injection port 150, and then may be referred to as an injection-compression mold.

As shown in FIGS. 29-36, while the mold 100 is still arranged with a horizontal parting line, the mold 100 is now arranged with the mold core side 120 overlying the mold cavity side 140. Mold 100 now includes a stepped parting line, which may also be referred to a stepped runoff region 110.

As shown, the runoff region 110 of the mold cavity side 140 may be sectioned into runoff surface sections 144a, 144b and 144c. Runoff surface section 144a extends horizontally from the perimeter edge of the molding cavity 180, as well as the molded article 300, outwards to vertical runoff surface section 144b. Vertical runoff surface section 144b extends vertically between horizonal runoff surface sections 144a and 144c. Horizontal runoff surface section 114 extends from the vertical runoff surface section 144b to the outer edge of the mold 100. The vertical transition between the horizontal runoff surface sections 144a and 144c may be referred to a stepped transition.

As shown, the outermost perimeter of the runoff region 110 of the mold cavity side 140 includes an annular shoulder 112, which is defined by vertical runoff surface section 144b and horizontal runoff surface section 144c. Further as shown, the clamp ring 162 of the mold core side 120 has a clamp ring surface 174 (also part of the runoff surface 124) which clamps the sheet 200 between the clamp ring 162 of the mold core side 120 and the horizontal runoff surface section 144a of mold cavity side 140.

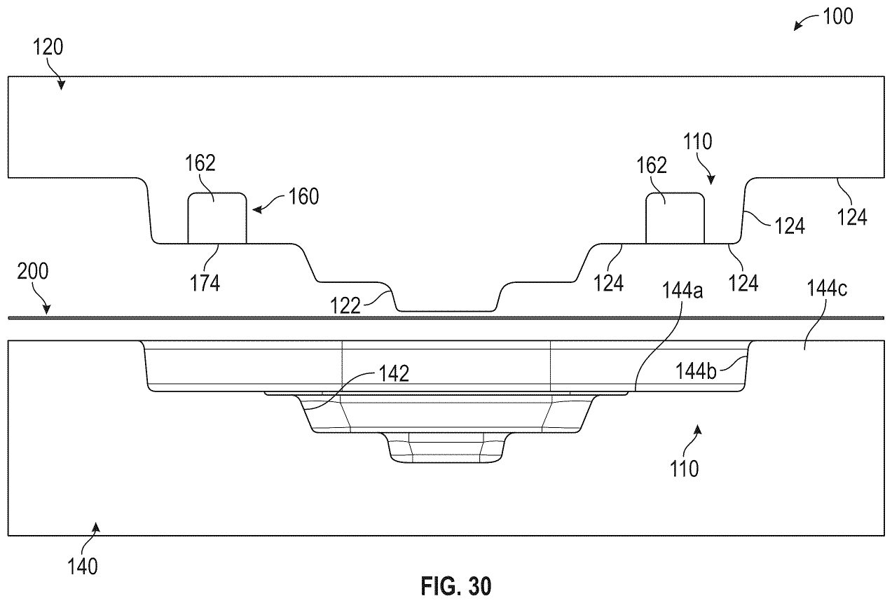

As shown by FIGS. 29-30, the sheet 200 may first be disposed between the mold core side 120 and the mold cavity side 140 in planar form. The sheet 200 may be supported by the annular shoulder 112 of the mold cavity side 140 with the retaining mechanism 160 in the retracted position.

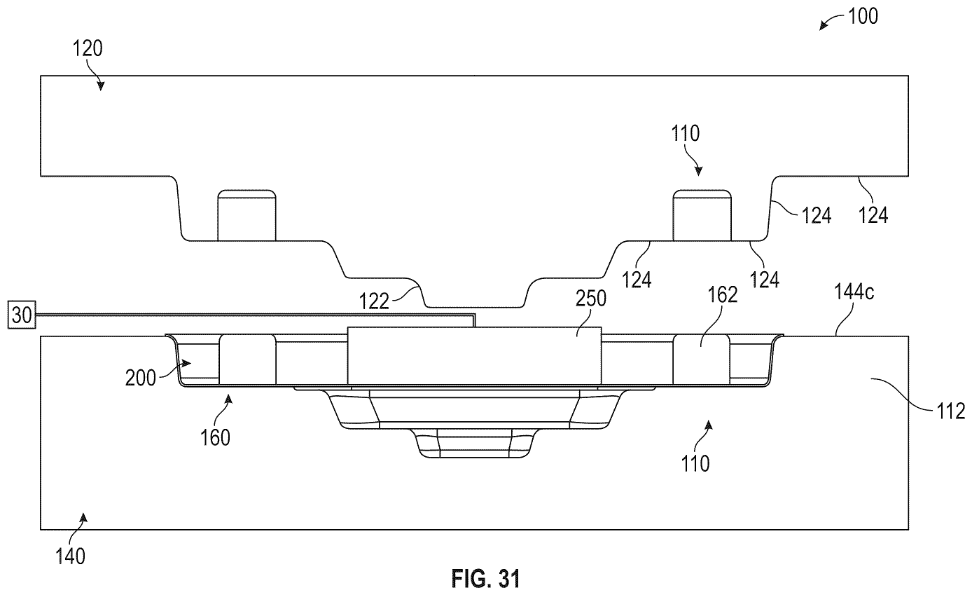

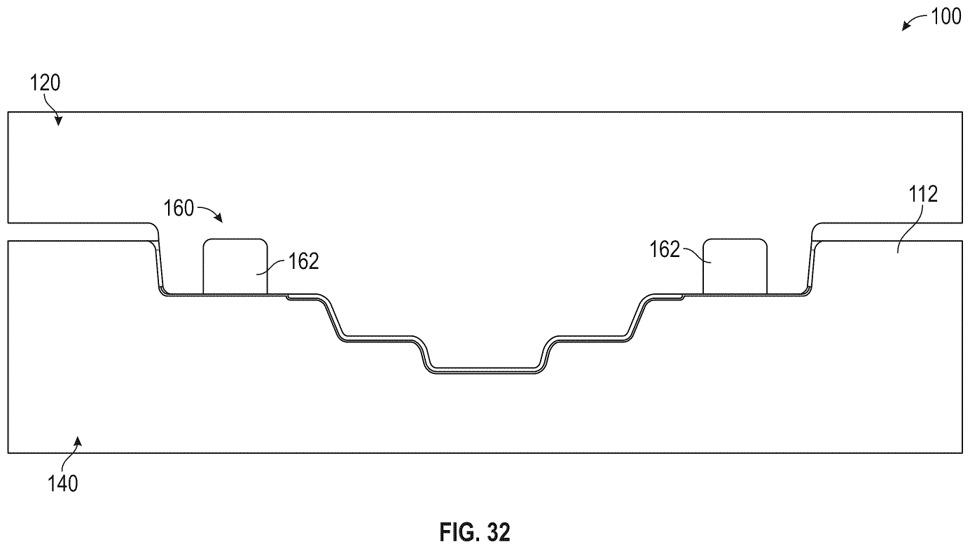

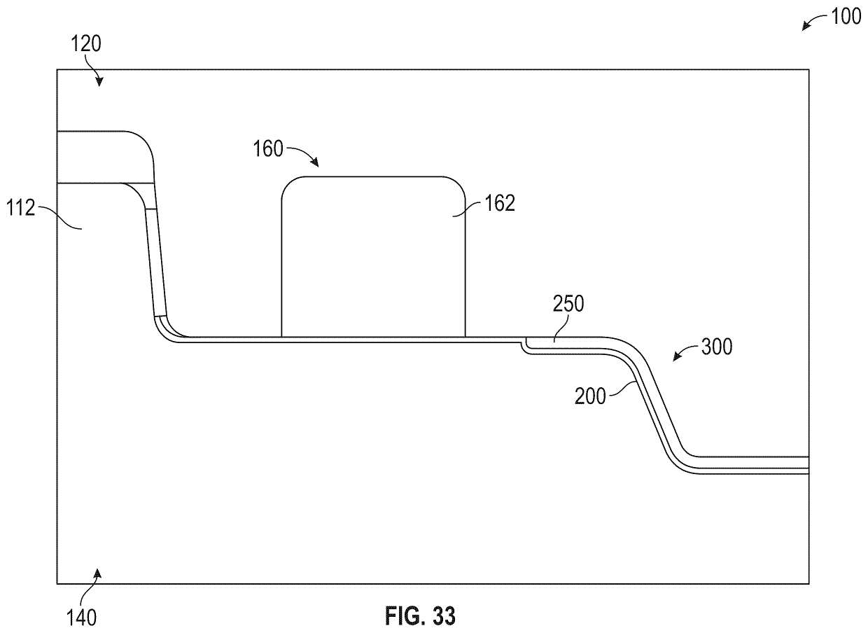

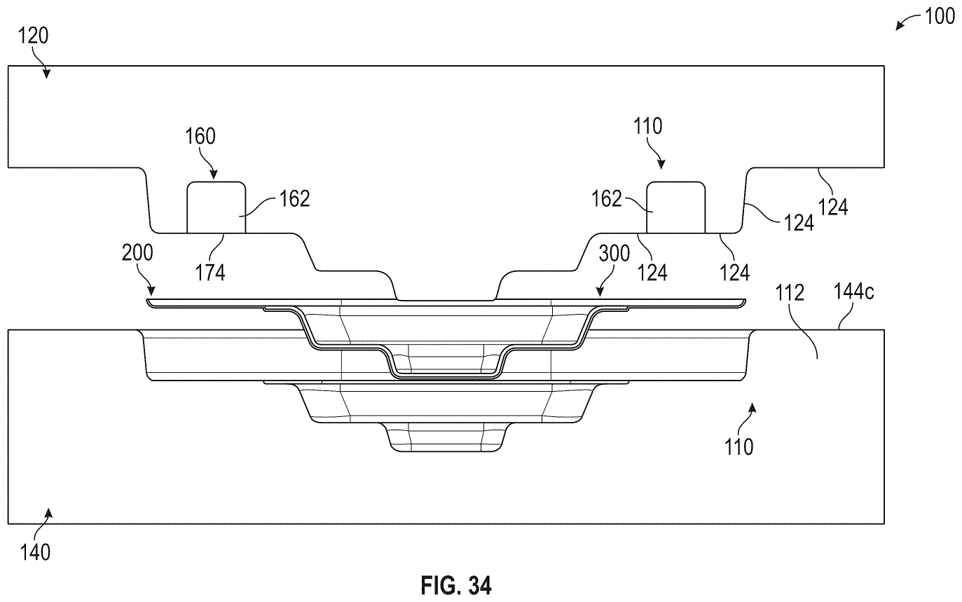

Thereafter, in FIG. 31, the retaining mechanism 160 may be extended to clamp/tension the sheet 200, and a charge of the polymer composition 250 may then be disposed within the open mold 100, particularly be an extrusion unit 30 (e.g. extruder with a stationary screw) which is movable into and out of the space between the mold core side 120 and mold cavity side 140. The mold 100 is then closed as shown in FIGS. 32-33 to compression mold the polymer composition 250, and the article 300 subsequently demolded as shown in FIGS. 34-36.

As may therefore now be appreciated, the present disclosure relates to a method for method for forming a composite article comprising supplying a sheet, supplying a mold including a first side having a location for injection of a polymer composition and a second side away from the first side, positioning the sheet in the mold, and introducing the polymer composition into the mold and forming the composite article wherein the composite article has a corresponding first side proximate to the location for injection of polymer composition and a second side away from the location for injection of the polymer composition. A majority portion of the sheet is located more towards the second side of the article away from the location for injection of the polymer composition than the first side of the article.

In addition, as may be further appreciated, the present disclosure relates to method for forming a composite article comprising: supplying a polymer composite sheet containing an additive to promote EMI shielding; supplying a mold including a first side having a location for injection of a polymer composition and a second side away from the first side, positioning the polymer composite sheet in the mold and introducing the polymer composition into the mold and forming the composite article wherein the composite article has a corresponding first side proximate to the location for injection of a polymer composition and a second side away from the location for injection of the polymer composition. A majority portion of the polymer composite sheet is located more towards the second side of the composite article away from the location for injection of the polymer composition than the first side of the article.

In product form, it may also be appreciated that the present disclosure relates to a composite article comprising a first side and a second side, wherein the first side of the composite article is the side of the article where a polymer composition was injected and the second side of the article is the side of the article away from the location for injection of the polymer composition. The composite article includes a sheet, wherein a majority portion of the sheet is located more towards a second side of the composite article than a first side of the composite article.

In addition, it is also contemplated herein that one may provide a method for forming a composite article comprising supplying a sheet, and supplying a mold including a first side which opens for introduction of a polymer composition and a second side away from the first side. Such mold may preferably be a compression mold. With the mold open, one may then selectively position and tension the sheet in the mold. This may then be followed by introduction of the polymer composition into the mold. The polymer composition may include thermoplastic or thermoset compositions. The polymer composition may also preferably be a charge of polymer composition that may be provided out of an extruder. Upon closing of the mold one can then form the composite article wherein the composite article has a corresponding first side proximate to the first side of the mold that opens for introduction of a polymer composition and a second side away or opposite from the first side. A majority portion of the sheet can now be located more towards the second side of the article than the first side of the article.

While particular embodiments of the present invention have been described, it should be understood that various changes, adaptations and modifications can be made therein without departing from the spirit of the invention and the scope of the appended claims. The scope of the invention should, therefore, be determined not with reference to the above description, but instead should be determined with reference to the appended claims along with their full scope of equivalents. Furthermore, it should be understood that the appended claims do not necessarily comprise the broadest scope of the invention which the Applicant is entitled to claim, or the only manner(s) in which the invention may be claimed, or that all recited features are necessary.

### LISTING OF REFERENCE CHARACTERS

10 mold press
20 injection unit
30 extrusion unit
100 mold
110 runoff region
112 annular shoulder
120 mold core side
122 core side molding surface
124 core side runoff surface
126 core side mold block
140 mold cavity side
142 cavity side molding surface
144 cavity side runoff surface (also 144a, 144b, 144c)
146 cavity side mold block
148 cylindrical recess
150 injection port
160 (spring loaded) retaining mechanism
162 (closed loop) clamp ring
164 threaded fasteners
166 shaft
168 counterbore
170 bias member (compression spring)
172 cylindrical recess
174 clamp ring surface
180 molding cavity
200 sheet
210 sheet first side
220 sheet second side
230 sheet through-openings
250 polymer composition
300 article/part
302 article A-side/surface
304 article B-side/surface

What is claimed is:

1. A method for forming a composite article comprising:
supplying at least one metal sheet, optionally in a form of a metal mesh providing EMI shielding;
supplying a mold having a molding cavity disposed between a mold first side and a mold second side, and having at least one injection port disposed on the mold first side to inject a polymer composition into the molding cavity;
positioning the metal sheet in the molding cavity between the mold first side and the mold second side;
introducing the polymer composition into the molding cavity and forming the article wherein the article has an article first side and an article second side formed by the mold first side and a mold second side, respectively; and
wherein a majority portion of the metal sheet is located more towards the article second side than the article first side.

2. The method of claim 1 wherein the mold first side is a mold cavity side of the mold and the mold second side is a mold core side of the mold.

3. The method of claim 1 wherein the mold first side is a mold core side of the mold and the mold second side is a mold cavity side of the mold.

4. The method of claim 1 wherein the metal sheet has a thickness in the range of 0.01 mm to 0.5 mm.

5. The method of claim 1 wherein the metal sheet comprises one or a plurality of metal layers.

6. The method of claim 1 wherein the article has a thickness in the range of 1.0 mm to 6.0 mm.

7. The method of claim 1 wherein the metal sheet is present as a metal mesh that has a mesh size in the range of 40 mesh/inch to 300 mesh/inch.

8. The method of claim 1 wherein the metal sheet is tensioned by the mold.

9. The method of claim 1 wherein the metal sheet is selected from steel, aluminum, copper, nickel, iron or metal alloys.

10. The method of claim 1 wherein the polymer composition includes one or more of the following additives: graphite, graphene, metal whiskers, glass, carbon black, metal oxide, a foaming agent, a ferrite and/or a flame retardant.

11. The method of claim 10 wherein the flame retardant comprises an intumescent flame retardant.

12. The method of claim 11 wherein the intumescent flame retardant comprises a non-halogenated flame retardant.

13. The method of claim 12 wherein the non-halogenated flame retardant is present at a level in the range of 20.0 % (wt.) to 50.0 % (wt.).

14. £ The method of claim 1 wherein the majority portion comprises 60% or more of the metal sheet that located more towards the article second side than the article first side.

15. A method for forming a composite article comprising:
supplying at least one polymer composite sheet with EMI shielding; and
supplying a mold having a molding cavity disposed between a mold first side and a mold second side, and having at least one injection port disposed on the mold first side to inject a polymer composition into the molding cavity;
positioning the polymer composite sheet in the molding cavity between the mold first side and the mold second side;
introducing the polymer composition into the molding cavity and forming the article wherein the article has an article first side and an article second side formed by the mold first side and a mold second side, respectively; and
wherein a majority portion of the polymer composite sheet is located more towards the article second side than the article first side.

16. The method of claim 15 wherein the mold first side is a mold cavity side of the mold and the mold second side is a mold core side of the mold.

17. The method of claim 15 wherein the mold first side is a mold core side of the mold and the mold second side is a mold cavity side of the mold.

18. The method of claim 15 wherein the polymer composite sheet with EMI shielding has a thickness in the range of 0.50 mm to 5.0 mm.

19. The method of claim 15 wherein the polymer composite sheet includes a metal sheet, optionally in a form of a metal mesh.

20. The method of claim 15 wherein the polymer composite sheet includes one or more of the following additives: graphene, graphite, metal whiskers, glass, carbon black, or a metal oxide.

21. The method of claim 15 wherein the polymer composition includes graphite, graphene, metal whiskers, glass, carbon black, metal oxide, a foaming agent, a ferrite, and/or a flame retardant.

22. The method of claim 15 wherein the majority portion comprises 60% or more of the polymer composite sheet located more towards the second side of the article than the first side of the article.

23. A composite article comprising:
an article first side and an article second side, wherein the article first side is a side of the article where a polymer composition was injected and the article second side of the article is a side of the article opposite the article first side, which is separated from the article first side by a thickness of the article;
wherein the article includes at least one metal sheet, optionally in a form of a metal mesh providing EMI shielding; and
wherein a majority portion of the at least one metal sheet is located more towards the article second side than the article first side.

24. The article of claim 23 in the article is at least a portion of a battery enclosure.

25. A method for forming a composite article comprising:
supplying an open mold, the mold having a molding cavity disposed between a mold first side and a mold second side
positioning a metal sheet, optionally in a form of a metal mesh, into the open mold, providing EMI shielding;
introducing a polymer composition into the open mold, wherein the polymer composition is disposed between the mold first side and the metal mesh;
closing the mold and compression molding the polymer composition;
forming the article wherein the article has an article first side and an article second side formed by the mold first side and a mold second side, respectively; and
wherein a majority portion of the metal sheet is located more towards the article second side than the article first side.
